(19) United States
(12) Patent Application Publication
(10) Pub. No.: US 2026/0255747 A1
(43) Pub. Date: Aug. 27, 2026

(54) DISPLAY DEVICE AND ELECTRONIC DEVICE INCLUDING THE SAME

(71) Applicant: Samsung Display Co., Ltd., Yongin-si (KR)

(72) Inventors: Yong Han LEE, Yongin-si (KR); Young Seok BAEK, Yongin-si (KR)

(21) Appl. No.: 19/447,213

(22) Filed: Jan. 13, 2026

(30) Foreign Application Priority Data
Feb. 27, 2025 (KR) 10-2025-0025939

(51) Int. Cl. H10H 20/857; H10H 20/84; H10H 20/853

(52) U.S. Cl. CPC H10H 20/857; H10H 20/84; H10H 20/853

(57) ABSTRACT

A display device includes a first partition wall disposed over a substrate, an inorganic layer disposed over the first partition wall, a second partition wall disposed over the first partition wall, a first electrode disposed over the second partition wall and the inorganic layer, an emission layer disposed over the first electrode, a second electrode disposed over the emission layer, and an encapsulation layer disposed over the second electrode. The encapsulation layer is in contact with an outer side surface of the inorganic layer.

### CROSS-REFERENCE TO RELATED APPLICATION

This application claims priority to Korean Patent Application No. 10-2025-0025939, filed on February 27, 2025, and all the benefits accruing therefrom under 35 U.S.C. §119, the content of which in its entirety is herein incorporated by reference.

### BACKGROUND

### a. Technical Field

Various embodiments of the present disclosure relate to a display device and an electronic device including the same.

### b. Description of Related Art

Recently, as interest in information display has increased, research and development on display devices have been continuously carried out.

### SUMMARY

The problem to be solved by the present disclosure is to provide a display device with improved reliability and an electronic device including the same.

The problem of the present disclosure is not limited to the above-mentioned problem, and other technical problems not mentioned will be clearly understood by those skilled in the art from the following description.

A display device according to an embodiment of the present disclosure for solving the above-mentioned problem includes a first partition wall disposed over a substrate, an inorganic layer disposed over the first partition wall, a second partition wall disposed over the first partition wall, a first electrode disposed over the second partition wall and the inorganic layer, an emission layer disposed over the first electrode, a second electrode disposed over the emission layer, and an encapsulation layer disposed over the second electrode. The encapsulation layer is in contact with an outer side surface of the inorganic layer.

The inorganic layer may be arranged on an edge area of the first partition wall, and may define therein an opening overlapping a central area of the first partition wall in a plan view.

The edge area may surround the central area.

The encapsulation layer may be in contact with a side surface of the second partition wall in the plan view.

The display device may further include a conductive layer between the first partition wall and the inorganic layer.

A width of the conductive layer may be the same as a width of the inorganic layer.

The conductive layer may be arranged on an edge area of the first partition wall, and may define therein an opening overlapping a central area of the first partition wall in the plan view.

The edge area may surround the central area in the plan view.

The display device may further include a connecting line between the substrate and the first partition wall.

The connecting line may be electrically connected to the first partition wall.

The display device may further include a connecting electrode between the second partition wall and the first electrode.

The connecting electrode may be electrically connected to the second partition wall.

The display device may further include an insulating layer between the connecting electrode and the first electrode.

The insulating layer may be in contact with an upper surface of the connecting electrode, and the second electrode may be in contact with a lower surface of the connecting electrode.

The encapsulation layer may be in contact with the lower surface of the connecting electrode.

A width of the insulating layer may be greater than a width of the second partition wall in the plan view.

The connecting electrode may be electrically isolated from the first electrode.

A width of the connecting electrode may be greater than a width of the second partition wall in the plan view.

The second electrode may be electrically connected to the connecting electrode.

An electronic device according to an embodiment of the present disclosure for solving the above-mentioned problem includes a processor and a display device. The display device includes pixels and is configured to display an image in the pixels under control of the processor. The display device includes a first partition wall disposed over a substrate, a second partition wall disposed over the first partition wall, an inorganic layer disposed on the first partition wall, an inner side of the inorganic layer being in contact with the second partition wall, a first electrode disposed over the second partition wall, an emission layer disposed over the first electrode, a second electrode disposed over the emission layer, and an encapsulation layer disposed over the second electrode. The encapsulation layer is in contact with an outer side surface of the inorganic layer.

Other details of the embodiments are included in the detailed description and drawings.

### BRIEF DESCRIPTION OF THE DRAWINGS

FIG. 1 is a block diagram illustrating an embodiment of a display device.

FIG. 2 is a block diagram illustrating an embodiment of one of sub-pixels of FIG. 1.

FIG. 3 is a plan view of an embodiment of a display panel of FIG. 1.

FIG. 4 is a plan view of an embodiment of a pixel of FIG. 3.

FIGS. 5 to 7 are cross-sectional views of an embodiment of one of sub-pixels of FIG. 4.

FIGS. 8 to 17 are cross-sectional views illustrating respective process steps of a method of manufacturing a display device according to an embodiment.

FIGS. 18 and 19 are cross-sectional views illustrating respective process steps of a method of manufacturing a display device according to an embodiment.

FIG. 20 is a block diagram of an electronic device according to an embodiment.

FIG. 21 shows schematic diagrams of an electronic device according to various embodiments.

### DETAILED DESCRIPTION

Hereinafter, embodiments according to the present disclosure are described in detail with reference to the accompanying drawings. It should be noted that in the following description, only portions necessary for understanding an operation according to the present disclosure may be described, and descriptions of other portions may be omitted in order not to obscure the subject matter of the present disclosure. In addition, the present disclosure may be embodied in other forms without being limited to embodiments described herein. However, embodiments of the present disclosure are described in detail in order for those skilled in the art to be able to readily implement the technical spirit of the present disclosure.

Throughout the specification, in a case where a component is “connected” to another component, the components may be “directly connected” or the components may be “indirectly connected” with another element interposed therebetween. Terms used herein are for describing specific embodiments and are not intended to limit the present disclosure. Throughout the specification, in a case where a certain portion “includes” a certain component, the portion may further include another component without excluding another component unless otherwise stated. “At least one of X, Y, or Z” and “at least one selected from a group consisting of X, Y, and Z” may be interpreted as X only, Y only, Z only, or any combination of two or more of X, Y, and Z (for example, XYZ, XYY, YZ, and ZZ). Here, “and/or” includes all combinations of one or more of corresponding configurations.

Here, terms such as “first” and “second” may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features may be positioned in a direction “on” the other elements or features. Therefore, in an embodiment, the term “under” may include both directions of on and under. In addition, the device may face in other directions (for example, rotated 90 degrees or in other directions) and thus the spatially relative terms used herein may be interpreted according thereto.

In addition, embodiments of the disclosure may be described here with reference to schematic diagrams (and intermediate structures) of the present disclosure, so that changes in a shape as shown due to, for example, manufacturing technology and/or a tolerance may be expected. Therefore, embodiments disclosed herein might not be construed as being limited to shown specific shapes, and should be interpreted as including, for example, changes in shapes that occur as a result of manufacturing. As described herein, the shapes shown in the drawings might not show actual shapes of areas of a device, and embodiments are not limited thereto.

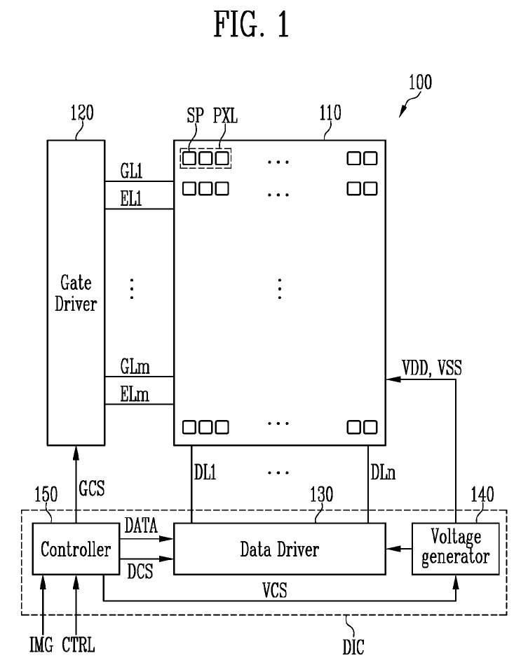

FIG. 1 is a block diagram illustrating an embodiment of a display device 100.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting device configured to generate light. Accordingly, each of the sub-pixels SP may generate light of a specific color such as red, green, blue, cyan, magenta, yellow, or the like. Two or more sub-pixels among the sub-pixels SP may constitute one pixel PXL. For example, as shown in FIG. 1, three sub-pixels SP may constitute one pixel PXL.

The gate driver 120 may be connected to the sub-pixels SP arranged in the row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating the start of each frame, a horizontal synchronization signal for outputting gate signals in synchronization with the timing at which data signals are applied, and the like.

In an embodiment, first to m-th emission control lines EL1 to ELm connected to the sub-pixels SP in the row direction may be further provided. In this case, the gate driver 120 may include an emission control driver configured to control the first to m-th emission control lines EL1 to ELm, and the emission control driver may operate under the control of the controller 150.

The gate driver 120 may be arranged at one side of the display panel 110. However, embodiments are not limited thereto. For example, the gate driver 120 may be divided into two or more drivers which are physically and/or logically divided, and such drivers may be arranged at one side of the display panel 110 and the other side of the display panel 110 opposite to the one side. As such, the gate driver 120 may be arranged around the display panel 110 in various forms according to embodiments.

The data driver 130 may be connected to the sub-pixels SP arranged in the column direction through the first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, or the like.

The data driver 130 may apply data signals including grayscale voltages corresponding to the image data DATA to the first to n-th data lines DL1 to DLn using voltages from the voltage generator 140. When a gate signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Accordingly, an image may be displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from outside the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a lower voltage level than the first power voltage VDD. In another embodiment, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting devices of the sub-pixels SP, a predetermined reference voltage may be applied to the first to n-th data lines DL1 to DLn, and the voltage generator 140 may generate such reference voltage.

The controller 150 may control various operations of the display device 100. The controller 150 may receive input image data IMG and a control signal CTRL for controlling the display of the input image data IMG from the outside. The controller 150 may provide the gate control signal GCS, the data control signal DCS, and the voltage control signal VCS in response to the control signal CTRL.

The controller 150 may output the image data DATA by converting the input image data IMG to be suitable for the display device 100 or the display panel 110. In an embodiment, the controller 150 may output the image data DATA by aligning the input image data IMG to be suitable for the sub-pixels SP in units of rows.

Two or more of the data driver 130, the voltage generator 140, and the controller 150 may be mounted in one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separated components within one driver integrated circuit DIC. In another embodiment, at least one of the data driver 130, the voltage generator 140, or the controller 150 may be provided as a component separate from the driver integrated circuit DIC.

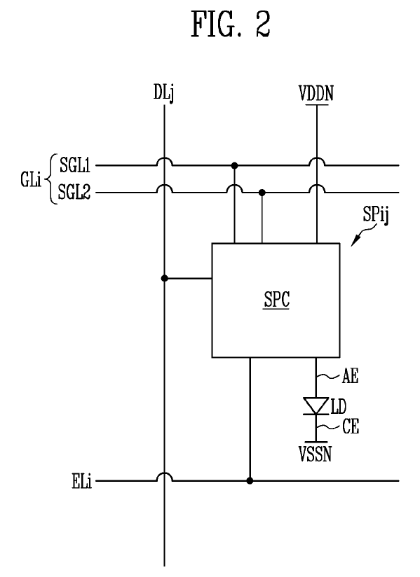

FIG. 2 is a block diagram illustrating an embodiment of one of the sub-pixels SP of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) may be shown as an example.

Referring to FIG. 2, the sub-pixel SPij may include a sub-pixel circuit SPC and a light emitting device LD.

The light emitting device LD may be connected between a first power voltage node VDDN and a second power voltage node VSSN. The first power voltage node VDDN may be a node transmitting the first power voltage VDD of FIG. 1, and the second power voltage node VSSN may be a node transmitting the second power voltage VSS of FIG. 1.

An anode electrode AE of the light emitting device LD may be connected to the first power voltage node VDDN through the sub-pixel circuit SPC, and a cathode electrode CE of the light emitting device LD may be connected to the second power voltage node VSSN. For example, the anode electrode AE of the light emitting device LD may be connected to the first power voltage node VDDN through one or more transistors included in the sub-pixel circuit SPC.

The sub-pixel circuit SPC may be connected to the i-th gate line GLi among the first to m-th gate lines GL1 to GLm of FIG. 1, the i-th emission control line ELi among the first to m-th emission control lines EL1 to ELm of FIG. 1, and the j-th data line DLj among the first to n-th data lines DL1 to DLn of FIG. 1. The sub-pixel circuit SPC may be configured to control the light emitting device LD according to signals received through these signal lines.

The sub-pixel circuit SPC may operate in response to a gate signal received through the i-th gate line GLi. The i-th gate line GLi may include one or more sub-gate lines. In an embodiment, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In an embodiment, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the emission control signal received through the i-th emission control line ELi, the sub-pixel circuit SPC may adjust a current flowing from the first power voltage node VDDN to the second power voltage node VSSN through the light emitting device LD according to the stored voltage. Accordingly, the light emitting device LD may generate light having luminance corresponding to the data signal.

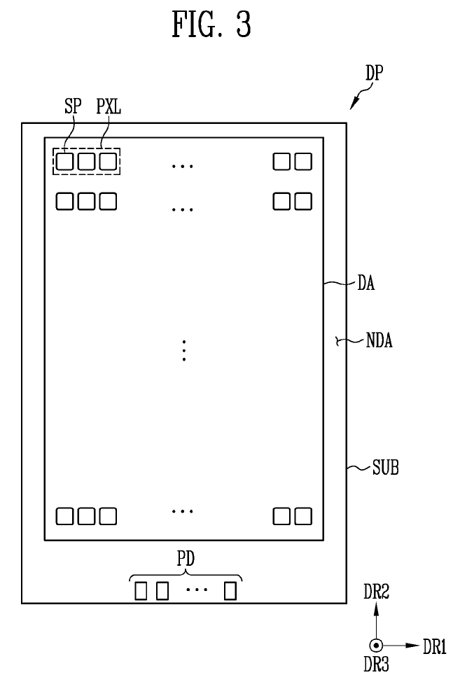

FIG. 3 is a plan view of an embodiment of the display panel 110 of FIG. 1. As used herein, the “plan view” is a view in a thickness direction (i.e., third direction DR3) of the display device 100.

Referring to FIG. 3, an embodiment DP of the display panel 110 of FIG. 1 may include a display area DA and a non-display area NDA. The display panel DP may display an image through the display area DA. The non-display area NDA may be arranged around the display area DA.

The display panel DP may include a substrate SUB, the sub-pixels SP, and pads PD. The sub-pixels SP may be arranged in the display area DA on the substrate SUB. The sub-pixels SP may be arranged in a matrix form in a first direction DR1 and a second direction DR2 intersecting the first direction DR1. However, embodiments are not limited thereto. For example, the sub-pixels SP may be arranged in a zigzag form in the first direction DR1 and the second direction DR2. For example, the sub-pixels SP may be arranged in a PenTile^{®} form. The first direction DR1 may be the row direction, and the second direction DR2 may be the column direction.

Two or more sub-pixels among the plurality of sub-pixels SP may constitute one pixel PXL.

A component for controlling the sub-pixels SP may be arranged in the non-display area NDA on the substrate SUB. For example, lines connected to the sub-pixels SP such as the first to m-th gate lines GL1 to GLm and the first to n-th data lines DL1 to DLn of FIG. 1 may be arranged in the non-display area NDA.

At least one of the gate driver 120, the data driver 130, the voltage generator 140, or the controller 150 of FIG. 1 may be integrated into the non-display area NDA of the display panel DP. In an embodiment, the gate driver 120 of FIG. 1 may be mounted on the display panel DP and arranged in the non-display area NDA. In another embodiment, the gate driver 120 may be implemented as an integrated circuit separated from the display panel DP.

The pads PD may be arranged in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP with other components of the display device 100 (see FIG. 1). In an embodiment, voltages and signals required for operations of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In an embodiment, a circuit board may be electrically connected to the pads PD by using a conductive adhesive member such as an anisotropic conductive film. The circuit board may be a flexible printed circuit board (FPCB) or a flexible film including a flexible material. The driver integrated circuit DIC may be mounted on the circuit board and electrically connected to the pads PD.

In an embodiment, the display area DA may have various shapes. The display area DA may have the shape of a closed loop including straight and/or curved sides. For example, the display area DA may have shapes such as a polygon, a circle, a semicircle, and an ellipse.

In an embodiment, the display panel DP may have a flat display surface. In another embodiment, the display panel DP may have an at least partially round display surface. In an embodiment, the display panel DP may be bendable, foldable, or rollable. In such cases, the display panel DP and/or the substrate SUB may include materials having a flexible property.

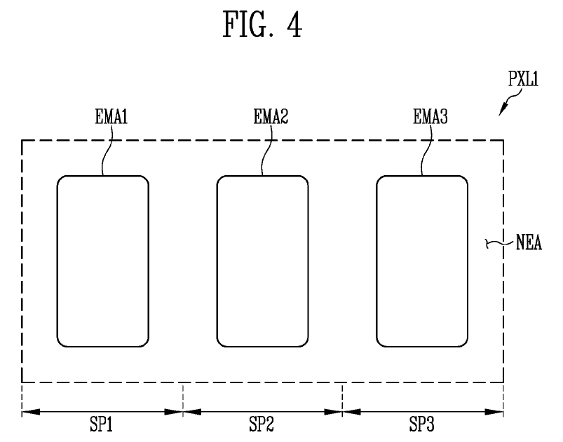

FIG. 4 is a plan view of an embodiment of the pixel PXL in FIG. 3.

Referring to FIG. 4, the pixel PXL may include first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third emission area EMA3 and the non-emission area NEA around the third emission area EMA3.

The first emission area EMA1 may be an area where light is emitted from an emission layer corresponding to the first sub-pixel SP1. The second emission area EMA2 may be an area where light is emitted from an emission layer corresponding to the second sub-pixel SP2. The third emission area EMA3 may be an area where light is emitted from the emission layer corresponding to the third sub-pixel SP3. The first to third emission areas EMA1 to EMA3 may be understood as openings of a pixel defining layer PDL corresponding to the first to third sub-pixels SP1 to SP3, respectively.

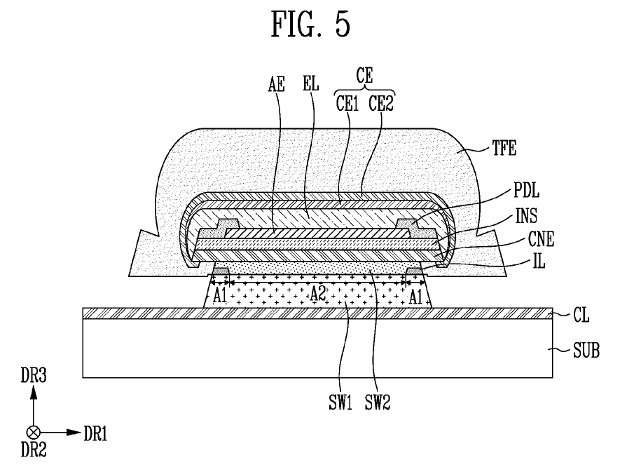

FIGS. 5 to 7 are cross-sectional views of an embodiment of one of the sub-pixels of FIG. 4.

Referring to FIGS. 5 to 7, the substrate SUB may include a base layer and a circuit layer. The base layer may include polyimide (PI), glass, silicon wafer, or the like. The circuit layer includes conductive patterns and insulating layers, and the conductive patterns may function as sub-pixel circuits (see SPC in FIG. 2) and various lines. The circuit layer may include circuit elements, including transistors and at least one capacitor. Each transistor may include a semiconductor portion including a source region, a drain region, and a channel region, and a gate electrode overlapping the semiconductor portion. Each capacitor may include electrodes spaced apart from each other in a third direction DR3 with an insulating layer interposed therebetween. The lines of the circuit layer may include signal lines, e.g., gate lines, emission control lines, data lines, and the like.

A connecting line CL may be arranged on the substrate SUB. The connecting line CL may be formed on the entirety of the substrate SUB, but is not necessarily limited thereto. In an embodiment, the connecting line CL may include titanium (Ti), but is not necessarily limited thereto.

A first partition wall SW1 may be arranged on the connecting line CL. The first partition wall SW1 may be arranged directly on the connecting line CL. The first partition wall SW1 may be electrically connected to the connecting line CL. The first partition wall SW1 may include aluminum (Al), but is not necessarily limited thereto.

An inorganic layer IL may be arranged on the first partition wall SW1. The inorganic layer IL may act to prevent or mitigate moisture permeation to the inside by contacting or being coupled to an encapsulation layer TFE, which will be described below. The inorganic layer IL may be arranged on a first area A1 of the first partition wall SW1. The first area A1 may mean an edge area of the first partition wall SW1. The inorganic layer IL may define therein an opening overlapping a second area A2 of the first partition wall SW1 in a plan view. The inorganic layer IL may have a ring shape in a plan view. The second area A2 may mean a central area of the first partition wall SW1. The second area A2 may be surrounded by the first area A1. The width of the first area A1 in the first direction DR1 may be smaller than the width of the second area A2 in the first direction DR1, but is not necessarily limited thereto. The area of the first area A1 may be smaller than the area of the second area A2, but is not necessarily limited thereto.

In an embodiment, the inorganic layer IL may include, but is not necessarily limited to, at least one of a silicon nitride (SiNx), a silicon oxide (SiOx), a silicon oxynitride (SiOxNy), an aluminum oxide (AlxOy), a titanium oxide (TiOx), a tantalum oxide (TaxOy), a hafnium oxide (HfOx), or a zinc oxide (ZnOx).

As shown in FIG. 5, the thickness of the inorganic layer IL in the third direction DR3 may be smaller than the thickness of a second partition wall SW2 in the third direction DR3. In this case, the second partition wall SW2 may be in contact with a side surface and an upper surface of the inorganic layer IL.

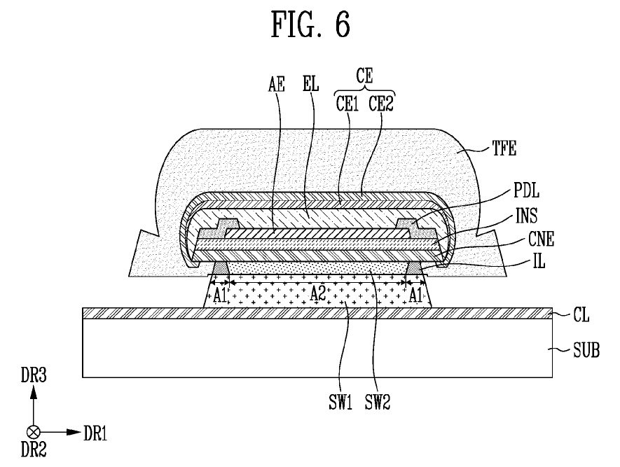

According to an embodiment, as shown in FIG. 6, the thickness of the inorganic layer IL in the third direction DR3 may be the same as the thickness of the second partition wall SW2 in the third direction DR3. In this case, the second partition wall SW2 may be in contact with a side surface (or edge) of the inorganic layer IL, not an upper surface (or a top surface) of the inorganic layer IL. The upper surface (or a top surface) of the inorganic layer IL may be directly in contact with a lower surface of a connecting electrode CNE.

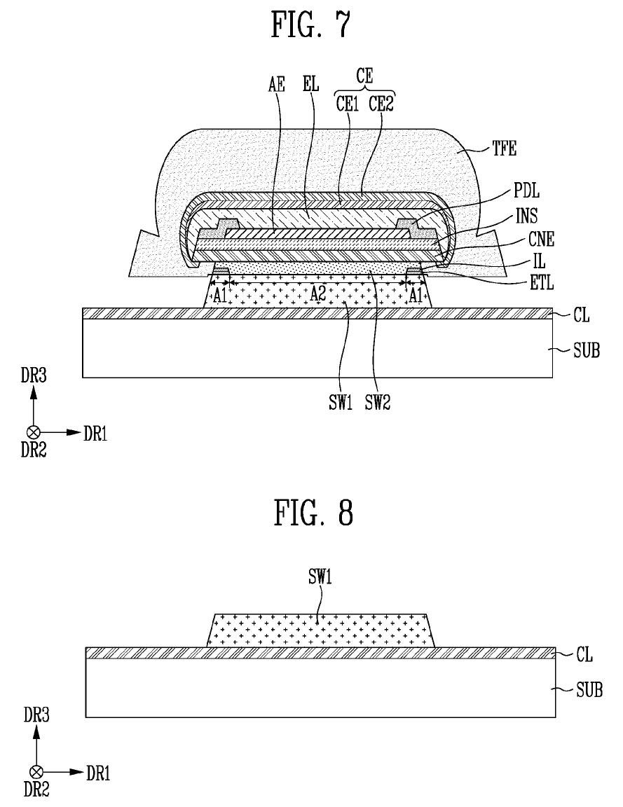

As shown in FIGS. 5 and 6, the inorganic layer IL may be arranged directly on the first partition wall SW1. According to an embodiment, as shown in FIG. 7, a conductive layer ETL may be further arranged between the inorganic layer IL and the first partition wall SW1. The conductive layer ETL may be arranged directly on the first partition wall SW1, and the inorganic layer IL may be arranged on the conductive layer ETL directly. When the conductive layer ETL is formed on the first partition wall SW1 and the inorganic layer IL is formed on the conductive layer ETL, arcing may be prevented or mitigated from occurring in a process of forming the inorganic layer IL.

The conductive layer ETL may be arranged on the first area A1 of the first partition wall SW1. As an example, the conductive layer ETL may be arranged on the edge area of the first partition wall SW1. The conductive layer ETL may define therein an opening overlapping the second area A2 of the first partition wall SW1 in a plan view. For example, the conductive layer ETL may define therein an opening overlapping the central area of the first partition wall SW1 in a plan view. The first area A1 of the first partition wall SW1 may surround the second area A2 of the first partition wall SW1.

The width of the conductive layer ETL in the first direction DR1 may be the same as the width of the inorganic layer IL in the first direction DR1. In an embodiment, the width of an upper surface of the conductive layer ETL in the first direction DR1 may be the same as the width of a lower surface of the inorganic layer IL in the first direction DR1. The conductive layer ETL may completely overlap the inorganic layer IL in a plan view. For example, the conductive layer ETL and the inorganic layer IL may be simultaneously etched in the same process, but are not necessarily limited thereto. The thickness of the conductive layer ETL in the third direction DR3 may be smaller than the thickness of the inorganic layer IL in the third direction DR3, but is not necessarily limited thereto.

The conductive layer ETL may include at least one of an indium tin oxide (ITO), an indium zinc oxide (IZO), a zinc oxide (ZnOx), an indium gallium zinc oxide (IGZO), or an indium tin zinc oxide (ITZO), but is not necessarily limited thereto.

The second partition wall SW2 may be arranged on the first partition wall SW1 and/or the inorganic layer IL. The second partition wall SW2 may be arranged on a portion of the first partition wall SW1 exposed by the opening of the inorganic layer IL. The second partition wall SW2 may be in contact with the portion of the first partition wall SW1 exposed by the opening of the inorganic layer IL. The second partition wall SW2 may be electrically connected to the first partition wall SW1. The second partition wall SW2 may be arranged directly on the inorganic layer IL. The second partition wall SW2 may be in contact with the upper surface and/or the side surface of the inorganic layer IL.

A connecting electrode CNE may be arranged on the second partition wall SW2 and the inorganic layer IL. The connecting electrode CNE may be arranged directly on the second partition wall SW2. A lower surface (or a second surface) of the connecting electrode CNE may be in contact with the second partition wall SW2. The connecting electrode CNE may be electrically connected to the second partition wall SW2.

The width of the connecting electrode CNE in the first direction DR1 may be greater than the width of the second partition wall SW2 in the first direction DR1. For example, an edge of the connecting electrode CNE may protrude farther than an edge of the second partition wall SW2 in the first direction DR1. The width of the connecting electrode CNE in the first direction DR1 may be greater than the width of the first partition wall SW1 in the first direction DR1. For example, the edge of the connecting electrode CNE may protrude farther than an edge of the first partition wall SW1 in the first direction DR1. Accordingly, the connecting electrode CNE may form a tip structure protruding beyond the first partition wall SW1 and/or the second partition wall SW2.

The connecting electrode CNE may include the same material as the connecting line CL. For example, the connecting electrode CNE and the connecting line CL may include titanium (Ti), but are not necessarily limited thereto.

An insulating layer INS may be arranged on the connecting electrode CNE. The insulating layer INS may be arranged directly on the connecting electrode CNE. The insulating layer INS may be in contact with an upper surface (or a first surface) of the connecting electrode CNE.

In an embodiment, the width of the insulating layer INS in the first direction DR1 may be greater than the width of the first partition wall SW1 in the first direction DR1. An edge of the insulating layer INS may protrude farther than the edge of the first partition wall SW1. The width of the insulating layer INS in the first direction DR1 may be greater than the width of the second partition wall SW2 in the first direction DR1. The edge of the insulating layer INS may protrude farther than the edge of the second partition wall SW2. Accordingly, the insulating layer INS may form a tip structure protruding beyond the first partition wall SW1 and/or the second partition wall SW2 together with the connecting electrode CNE.

The insulating layer INS may include an inorganic material. As an example, the insulating layer INS may include, but is not necessarily limited to, at least one of a silicon nitride (SiNx), a silicon oxide (SiOx), a silicon oxynitride (SiOxNy), an aluminum oxide (AlxOy), a titanium oxide (TiOx), a tantalum oxide (TaxOy), a hafnium oxide (HfOx), or a zinc oxide (ZnOx).

The anode electrode AE (or a first electrode) may be arranged on the insulating layer INS. The anode electrode AE may be arranged directly on the insulating layer INS. The anode electrode AE may be electrically isolated from the connecting electrode CNE by the insulating layer INS.

The pixel defining layer PDL may be arranged on the insulating layer INS and/or the anode electrode AE. The pixel defining layer PDL may define therein an opening which at least partially exposes the anode electrode AE. For example, the pixel defining layer PDL may surround an edge of the anode electrode AE.

In an embodiment, an edge of the pixel defining layer PDL may protrude farther than the edge of the first partition wall SW1. The edge of the pixel defining layer PDL may protrude farther than the edge of the second partition wall SW2. Accordingly, the pixel defining layer PDL may form a tip structure protruding beyond the first partition wall SW1 and/or the second partition wall SW2 together with the insulating layer INS and/or the connecting electrode CNE.

An emission layer EL may be arranged on the insulating layer INS, the pixel defining layer PDL, and/or the anode electrode AE. The respective emission layers EL of the sub-pixels SP1 to SP3 may be separated from each other. For example, the respective emission layers EL of the sub-pixels SP1 to SP3 may be separated from each other by a tip structure of the pixel defining layer PDL, the insulating layer INS, and/or the connecting electrode CNE. Accordingly, the respective emission layers EL of the sub-pixels SP1 to SP3 may be spaced apart from each other. The emission layer EL of each of the sub-pixels SP1 to SP3 may generate light of a red, green, or blue color.

The cathode electrode CE (or a second electrode) may be arranged on the emission layer EL. The cathode electrode CE may be arranged directly on the emission layer EL. The cathode electrode CE may cover the emission layer EL. The respective cathode electrodes CE of the sub-pixels SP1 to SP3 may be separated from each other. The respective cathode electrodes CE of the sub-pixels SP1 to SP3 may be spaced apart from each other.

The cathode electrode CE may be in contact with the lower surface (or the second surface) of the connecting electrode CNE. The cathode electrode CE may be electrically connected to the connecting electrode CNE. The cathode electrode CE of each of the sub-pixels SP1 to SP3 may be electrically connected to the connecting line CL through the connecting electrode CNE, the second partition wall SW2, and/or the first partition wall SW1. The respective cathode electrodes CE of the sub-pixels SP1 to SP3 may be electrically connected to each other through the connecting line CL.

The cathode electrode CE may include a transparent conductive material. For example, the cathode electrode CE may include, but is not necessarily limited to, an indium gallium zinc oxide (IGZO).

The cathode electrode CE may include a first electrode layer CE1 and a second electrode layer CE2. The first electrode layer CE1 may be arranged between the emission layer EL and the second electrode layer CE2.

The encapsulation layer TFE may be arranged on the cathode electrode CE. The encapsulation layer TFE may prevent or mitigate oxygen and/or moisture from permeating the emission layer EL or the like. The encapsulation layer TFE may include a structure in which one or more inorganic films and one or more organic films are alternately stacked.

The encapsulation layer TFE may be in contact with the lower surface (or the second surface) of the connecting electrode CNE. The encapsulation layer TFE may be in contact with the first partition wall SW1 and/or the second partition wall SW2. The encapsulation layer TFE may be in contact with the side surface of the inorganic layer IL. When the encapsulation layer TFE is in contact with the side surface (e.g., outer side surface) of the inorganic layer IL as describe above, moisture permeation may be prevented or mitigated by improving an adhesive force of the encapsulation layer TFE. For example, the cathode electrode CE may be oxidized or the emission layer EL may be damaged due to interfacial moisture permeation between the encapsulation layer TFE and the first partition wall SW1 and/or the second partition wall SW2, thereby reducing the reliability of a display device if there is no inorganic layer IL of which outer side surface is in contact with the encapsulation layer TFE. Accordingly, according to the above-described embodiment, the encapsulation layer TFE is in contact with the inorganic layer IL arranged on the first partition wall SW1, thereby improving the adhesive force of the encapsulation layer TFE, thereby preventing or mitigating moisture permeation and improving the reliability of the display device.

Next, a method of manufacturing the display device according to the above-described embodiment will be described.

FIGS. 8 to 17 are cross-sectional views illustrating respective process steps of a method of manufacturing the display device according to an embodiment. FIGS. 8 to 17 are cross-sectional views for explaining the method of manufacturing the display device of FIGS. 1 to 5, which are briefly shown and repetitive descriptions are omitted for convenience of description.

Referring to FIG. 8, first, the connecting line CL and the first partition wall SW1 are sequentially formed on the substrate SUB. The connecting line CL may be formed on the entirety of the substrate SUB. The first partition wall SW1 may be partially formed on the connecting line CL. In an embodiment, the connecting line CL may include titanium (Ti), and the first partition wall SW1 may include aluminum (Al), but are not necessarily limited thereto.

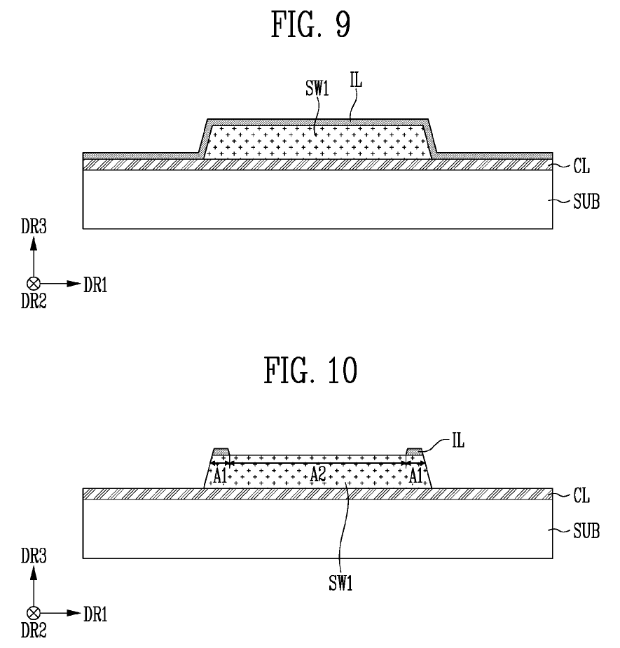

Referring to FIG. 9, the inorganic layer IL is then formed on the connecting line CL and/or the first partition wall SW1. The inorganic layer IL may be formed over the entirety of the substrate SUB. The inorganic layer IL may include, but is not necessarily limited to, at least one of a silicon nitride (SiNx), a silicon oxide (SiOx), a silicon oxynitride (SiOxNy), an aluminum oxide (AlxOy), a titanium oxide (TiOx), a tantalum oxide (TaxOy), a hafnium oxide (HfOx), or a zinc oxide (ZnOx).

Referring to FIG. 10, the inorganic layer IL is then etched. The inorganic layer IL may be etched and partially formed on the first partition wall SW1. As an example, the inorganic layer IL may be formed on the first area A1 (or the edge area) of the first partition wall SW1. The inorganic layer IL may define therein an opening overlapping the second area A2 (or the central area) of the first partition wall SW1 in a plan view. The first area A1 of the first partition wall SW1 may surround the second area A2 of the first partition wall SW1.

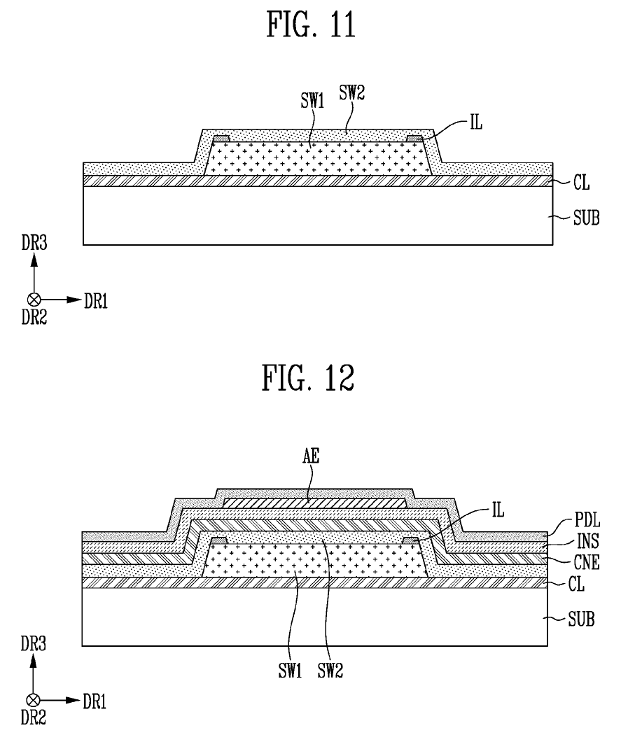

Referring to FIG. 11, the second partition wall SW2 is then formed on the connecting line CL, the first partition wall SW1, and/or the inorganic layer IL. The second partition wall SW2 may be formed over the entirety of the substrate SUB. The second partition wall SW2 may include aluminum (Al), but is not necessarily limited thereto.

Referring to FIG. 12, the connecting electrode CNE, the insulating layer INS, the anode electrode AE, and/or the pixel defining layer PDL are then sequentially formed over the second partition wall SW2. The connecting electrode CNE, the insulating layer INS, and/or the pixel defining layer PDL may be formed over the entirety of the substrate SUB.

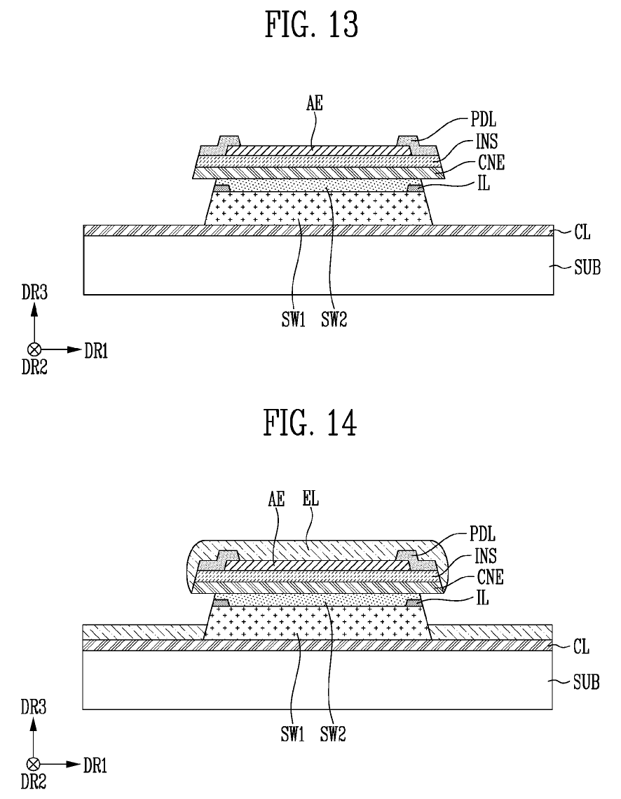

Referring to FIG. 13, the pixel defining layer PDL, the insulating layer INS, the connecting electrode CNE, and/or the second partition wall SW2 are then etched. The pixel defining layer PDL, the insulating layer INS, the connecting electrode CNE, and/or the second partition wall SW2 may be simultaneously etched in the same process, but are not necessarily limited thereto.

In an embodiment, the second partition wall SW2 may be etched to have the smaller width in the first direction DR1 than the connecting electrode CNE. For example, the edge of the second partition wall SW2 may be positioned further inward relative to the edge of the connecting electrode CNE. Accordingly, the connecting electrode CNE may form a tip structure protruding beyond the second partition wall SW2.

Referring to FIG. 14, the emission layer EL is then formed. The emission layer EL may be formed over the entirety of the substrate SUB. The emission layer EL may be formed on the pixel defining layer PDL, the anode electrode AE, and/or the connecting line CL. The emission layer EL formed on the pixel defining layer PDL and the anode electrode AE and the emission layer EL formed on the connecting line CL may be separated from each other. For example, the emission layer EL formed on the pixel defining layer PDL and the anode electrode AE and the emission layer EL formed on the connecting line CL may be separated from each other by the tip structure of the connecting electrode CNE.

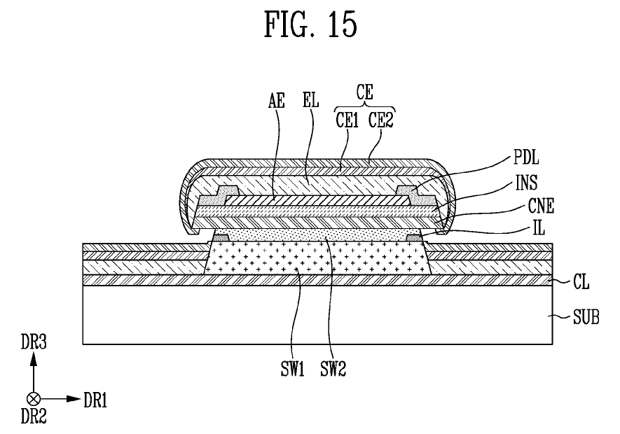

Referring to FIG. 15, the cathode electrode CE is then formed. The cathode electrode CE may be formed over the entirety of the substrate SUB. The cathode electrode CE may be formed on the emission layer EL. In an embodiment, the first electrode layer CE1 and the second electrode layer CE2 of the cathode electrode CE may be sequentially formed on the emission layer EL and the connecting electrode CNE.

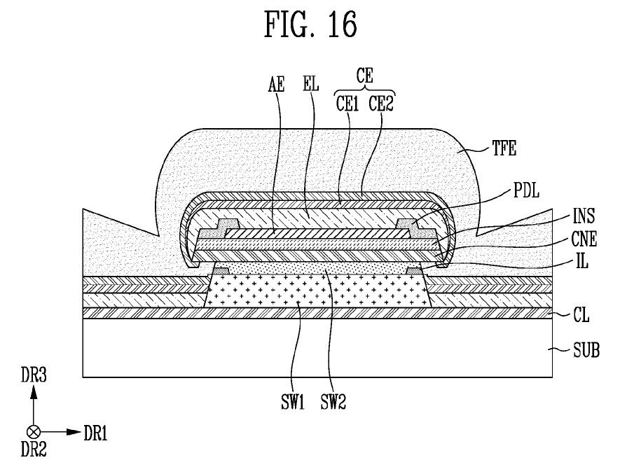

Referring to FIG. 16, the encapsulation layer TFE is then formed on the cathode electrode CE. The encapsulation layer TFE may be formed over the entirety of the substrate SUB. In an embodiment, the encapsulation layer TFE may be formed on the lower surface (or the second surface) of the connecting electrode CNE. The encapsulation layer TFE may be in contact with the lower surface (or the second surface) of the connecting electrode CNE. The encapsulation layer TFE may be formed on the first partition wall SW1 and/or the second partition wall SW2. The encapsulation layer TFE may be in contact with the first partition wall SW1 and/or the second partition wall SW2. The encapsulation layer TFE may be arranged on the side surface of the inorganic layer IL. The encapsulation layer TFE may be in contact with the side surface of the inorganic layer IL. As described above, when the encapsulation layer TFE is in contact with the side surface of the inorganic layer IL, moisture permeation may be prevented or mitigated by improving the adhesive force of the encapsulation layer TFE.

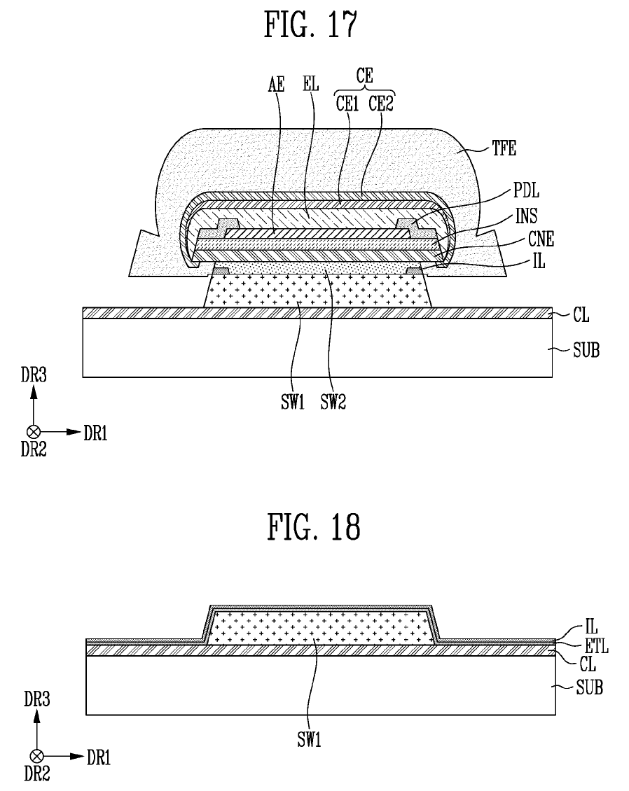

Referring to FIG. 17, the encapsulation layer TFE and the cathode electrode CE are then partially etched. The cathode electrode CE and the encapsulation layer TFE, except for the areas formed over the anode electrode AE and the emission layer EL, may be partially etched. In the process of etching the encapsulation layer TFE and the cathode electrode CE, the emission layer EL formed between the encapsulation layer TEF and the connecting line CL may be removed together. In this case, a space may be formed between the encapsulation layer TFE and the connecting line CL.

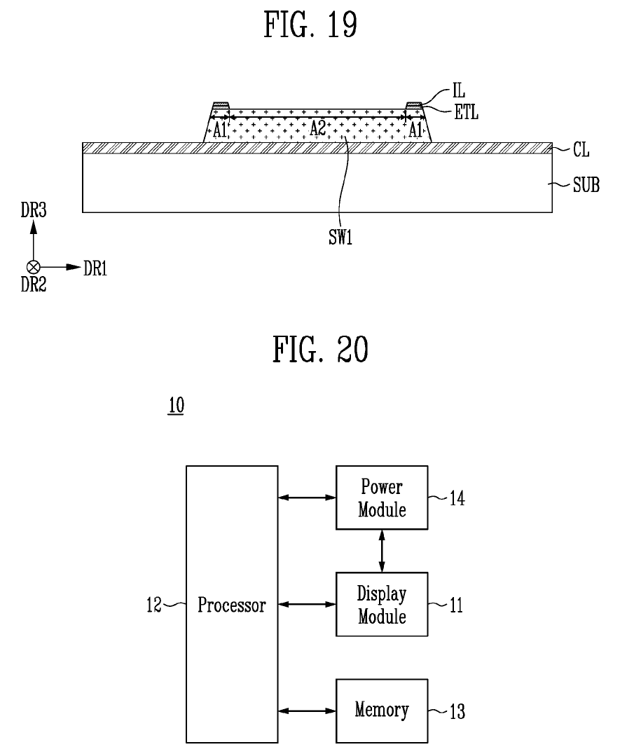

FIGS. 18 and 19 are cross-sectional views illustrating respective process steps of a method of manufacturing the display device according to an embodiment. FIGS. 18 and 19 are parts of cross-sectional views for explaining the method of manufacturing the display device of FIG. 7, which are briefly shown and repetitive descriptions are omitted for convenience of description.

Referring to FIG. 18, the conductive layer ETL may be formed on the connecting line CL and/or the first partition wall SW1, and the inorganic layer IL is formed on the conductive layer ETL. The conductive layer ETL may be formed over the entirety of the substrate SUB. The inorganic layer IL may be formed over the entirety of the substrate SUB.

The conductive layer ETL may include, but is not necessarily limited thereto, at least one of an indium tin oxide (ITO), an indium zinc oxide (IZO), a zinc oxide (ZnOx), an indium gallium zinc oxide (IGZO), and an indium tin zinc oxide (ITZO).

The inorganic layer IL may include, but is not necessarily limited to, at least one of a silicon nitride (SiNx), a silicon oxide (SiOx), a silicon oxynitride (SiOxNy), an aluminum oxide (AlxOy), a titanium oxide (TiOx), a tantalum oxide (TaxOy), a hafnium oxide (HfOx), and a zinc oxide (ZnOx).

Referring to FIG. 19, the conductive layer ETL and/or the inorganic layer IL are then etched. The conductive layer ETL and/or the inorganic layer IL may be etched and partially formed on the first partition wall SW1. The conductive layer ETL and the inorganic layer IL may be simultaneously etched in the same process, but are not necessarily limited thereto.

The conductive layer ETL and/or the inorganic layer IL may be formed on the first area A1 (or the edge area) of the first partition wall SW1. The conductive layer ETL and/or the inorganic layer IL may define therein an opening overlapping the second area A2 (or the central area) of the first partition wall SW1 in a plan view. The first area A1 of the first partition wall SW1 may surround the second area A2 of the first partition wall SW1.

Because the subsequent manufacturing process may be substantially the same as the process described with reference to FIGS. 11 to 17, repetitive descriptions will be omitted.

The display device 100 according to the above-described embodiment may be applied to various electronic devices. An electronic device according to the embodiment includes the display device 100 described above, and may further include a module or device having an additional function other than the display device 100.

FIG. 20 is a block diagram of an electronic device 10 according to an embodiment.

Referring to FIG. 20, the electronic device 10 according to an embodiment may include a display module 11, a processor 12, memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information necessary for an operation of the processor 12 or the display module 11. When the processor 12 executes an application stored in the memory 13, an image data signal and/or an input control signal are transmitted to the display module 11, and the display module 11 may process the received signal to output image information through a display screen, that is, a pixel.

The power module 14 may include a power supply module such as a power adapter or a battery device, and a power conversion module which converts power supplied by the power supply module to generate power necessary for the operation of the electronic device 10.

At least one of the above-described components of the electronic device 10 may be included in the display device according to the above-described embodiments. In addition, one or more of individual modules which are functionally included in one module may be included in the display device, and other individual modules except for the one or more individual modules may be provided separately from the display device. For example, the display device includes the display module 11, and the processor 12, the memory 13, and the power module 14 may be provided in the form of other devices in the electronic device 10 other than the display device.

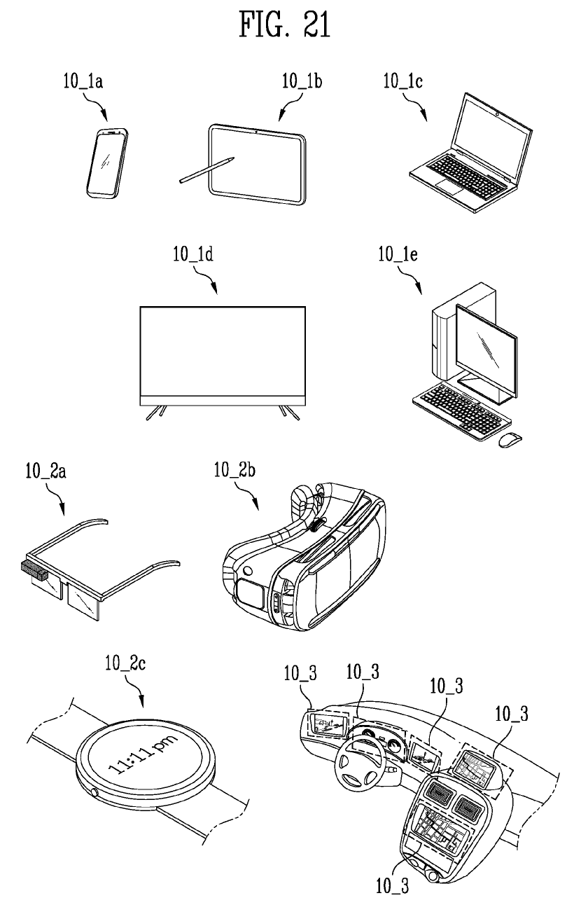

FIG. 21 shows schematic diagrams of an electronic device according to various embodiments.

Referring to FIG. 21, examples of various electronic devices to which a display device according to embodiments of the present disclosure is applied may include an electronic device for displaying images, such as a smartphone 10_1a, a tablet PC 10_1b, a laptop 10_1c, a television 10_1d, or a desk monitor 10_1e, as well as a wearable electronic device including a display module, such as smart glasses 10_2a, a head-mounted display 10_2b, or a smart watch 10_2c, and an automotive electronic device 10_3 including a display module such as an automotive dashboard, a center fascia, a Center Information Display (CID) placed on a dashboard, or a room mirror display.

Although specific embodiments have been described herein, other embodiments and variations may be derived from the above descriptions. Accordingly, the spirit of the present disclosure is not limited to these embodiments, but extends to the appended claims, various obvious modifications, and equivalents.

According to the above-mentioned embodiments of the present disclosure, an encapsulation layer is in contact with an inorganic layer arranged over a first partition wall, thereby improving an adhesive force of the encapsulation layer, thereby preventing or mitigating moisture permeation.

However, effects according to embodiments of the present disclosure are not limited to the above-mentioned descriptions, and a wider variety of effects are included herein.

What is claimed is:

1. A display device, comprising:
a first partition wall disposed over a substrate;
an inorganic layer disposed over the first partition wall;
a second partition wall disposed over the first partition wall;
a first electrode disposed over the second partition wall and the inorganic layer;
an emission layer disposed over the first electrode;
a second electrode disposed over the emission layer; and
an encapsulation layer disposed over the second electrode,
wherein the encapsulation layer is in contact with an outer side surface of the inorganic layer.

2. The display device according to claim 1, wherein the inorganic layer is arranged on an edge area of the first partition wall, and defines therein an opening overlapping a central area of the first partition wall in a plan view.

3. The display device according to claim 2, wherein the edge area surrounds the central area in the plan view.

4. The display device according to claim 1, wherein the encapsulation layer is in contact with a side surface of the second partition wall.

5. The display device according to claim 1, further comprising a conductive layer between the first partition wall and the inorganic layer.

6. The display device according to claim 5, wherein a width of the conductive layer is the same as a width of the inorganic layer.

7. The display device according to claim 5, wherein the conductive layer is arranged on an edge area of the first partition wall, and defines therein an opening overlapping a central area of the first partition wall in a plan view.

8. The display device according to claim 7, wherein the edge area surrounds the central area in the plan view.

9. The display device according to claim 1, further comprising a connecting line between the substrate and the first partition wall.

10. The display device according to claim 9, wherein the connecting line is electrically connected to the first partition wall.

11. The display device according to claim 1, further comprising a connecting electrode between the second partition wall and the first electrode.

12. The display device according to claim 11, wherein the connecting electrode is electrically connected to the second partition wall.

13. The display device according to claim 11, further comprising an insulating layer between the connecting electrode and the first electrode.

14. The display device according to claim 13, wherein the insulating layer is in contact with an upper surface of the connecting electrode; and
wherein the second electrode is in contact with a lower surface of the connecting electrode.

15. The display device according to claim 14, wherein the encapsulation layer is in contact with the lower surface of the connecting electrode.

16. The display device according to claim 13, wherein a width of the insulating layer is greater than a width of the second partition wall in a plan view.

17. The display device according to claim 11, wherein the connecting electrode is electrically isolated from the first electrode.

18. The display device according to claim 11, wherein a width of the connecting electrode is greater than a width of the second partition wall in a plan view.

19. The display device according to claim 11, wherein the second electrode is electrically connected to the connecting electrode.

20. An electronic device, comprising:
a processor; and
a display device including pixels and which displays an image in the pixels under control of the processor,
wherein the display device comprises:
a first partition wall disposed over a substrate;
a second partition wall disposed over the first partition wall;
an inorganic layer disposed on the first partition wall, an inner side of the inorganic layer being in contact with the second partition wall;
a first electrode disposed over the second partition wall;
an emission layer disposed over the first electrode;
a second electrode disposed over the emission layer; and
an encapsulation layer disposed over the second electrode,
wherein the encapsulation layer is in contact with an outer side surface of the inorganic layer.
